(19) United States
(12) Patent Application Publication
(10) Pub. No.: US 2010/0295141 A1
(43) Pub. Date: Nov. 25, 2010

(54) TWO COLOUR PHOTON DETECTOR

(75) Inventor: Paul Abbott, Hampshire (GB)

Correspondence Address: BUCHANAN, INGERSOLL & ROONEY PC, POST OFFICE BOX 1404, ALEXANDRIA, VA, 22313-1404, US

(73) Assignee: SELEX GALILEO LIMITED, Essex (GB)

(21) Appl. No.: 12/679,442

(22) PCT Filed: Sep. 16, 2008
(86) PCT No.: PCT/EP2008/062302

§ 371 Date: Mar. 22, 2010

(30) Foreign Application Priority Data
Sep. 24, 2007 (GB) 0718584.6

(51) Int. Cl. H01L 31/0216

(52) U.S. Cl. 257/432; 257/437; 257/437; 257/E31.121; 257/E31.119

(57) ABSTRACT

A two-color radiation detector includes a mesa-type multi-layered mercury-cadmium-telluride detector structure monolithically integrated on a substrate. The detector is responsive to two discrete wavelength ranges separated by a wavelength range to which the detector is not responsive. The detector further includes two contact points deposited on the layer disposed furthest away from the entry point of the radiation, the contact points being isolated with respect to each other by a trench disposed within the layer.

This invention relates to the field of solid state radiation detection, particularly to a two-colour radiation detector. More specifically, but not exclusively the invention relates to a two-colour infrared (IR) radiation detector capable of simultaneously detecting both colours.

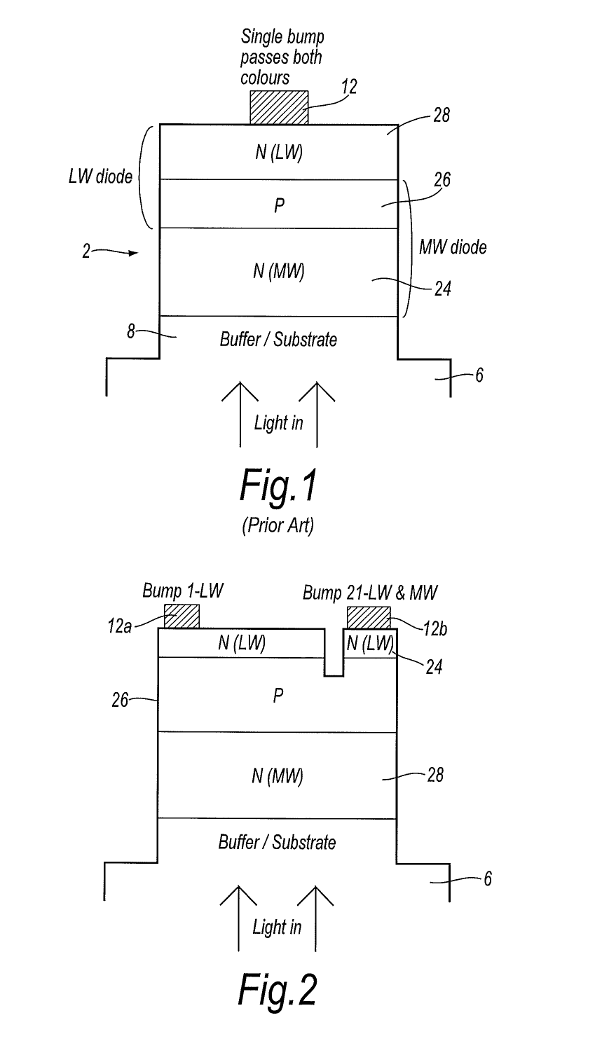

Typically, two-colour IR detectors possess a device structure which consists of two absorbing layers of the same doping type separated by a wide band gap layer of the opposite doping type. The band gaps of the two absorbing layers are chosen to correspond to the two ‘colours’ which are required. In the detector itself, the colour is selected by the polarity of the applied bias. Both colours are detected through a single contact bump, thereby preventing the design from allowing the two colours from being detected simultaneously. A cross-section of an individual pixel from such a detector is shown in FIG. 1. In this case, the absorbing layers are n-type while the barrier layer is p-type. Such known detectors are spatially coherent but not temporally coherent.

Simultaneous detection of two colours has been achieved in an independently accessible two-colour IR detector, which provides independent electrical access to each of two spatially co-located back-to-back photodiodes. The P-n-N-P structure was formed by two Hg₁₋ₓCdₓTe layers grown sequentially onto a cadmium-zinc-telluride, CdZnTe, substrate.

It is a disadvantage of such simultaneous two-colour IR detectors that a second contact must be applied to each pixel, such that each colour can be extracted through its own contact. As such, each pixel must now have two contact bumps, which increases the size of the pixel. Furthermore, currently available detector designs involve making contact to layers within the structure, i.e., not only the uppermost layer. For this, one or more trenches must be etched within each pixel (for example, see European Patent Application EP 0 747 962 A2). Etching trenches in each pixel requires that pixel area be allocated to them. This will therefore increase the minimum pixel size and compromise the maximum resolution available. In addition, contacting to different layers will inevitably require one or more contacts to be made to p-type material. Metal-semiconductor contacts are very difficult to make when the CdHgTe (CMT) is p-type.

Accordingly, there is provided an electromagnetic radiation detector responsive to two discrete wavelength ranges comprising a plurality of layers of semiconductor material comprising a substrate substantially transparent to electromagnetic radiation within and between the wavelength ranges; a first layer, doped to provide a first type of electrical conductivity, having a band gap selected for absorbing radiation within a first wavelength range; a second layer, doped to provide a second type of electrical conductivity, having a band gap selected for absorbing radiation within a second wavelength range; a third layer, doped to provide the first type of electrical conductivity, having a band gap selected for absorbing radiation within a third wavelength range; in which the first and third layers are doped n-type and the second layer is doped p-type.

Preferably, the detector further comprises two contact points disposed on the third layer. Furthermore, the semiconductor material is preferably a Group II-VI semiconductor material.

Ideally, the third layer is divided into two sections by a trench, the trench acting so as to isolate the contact points from each other.

Conveniently, the contacts are formed from metal deposited onto the pixel, the metal being bonded only to the n-type material.

The two wavelength ranges may be 2 μm to 2.5 μm and 3.7 μm to 4.5 μm.

The substrate may be comprised of gallium arsenide, GaAs; gallium arsenide on silicon, GaAs:Si; cadmium telluride, CdTe; cadmium zinc telluride, CdZnTe; cadmium telluride on silicon, CdTe:Si or cadmium telluride on sapphire, CdTe:sapphire.

The invention will now be described by way of example and with reference to the accompanying drawings, in which:

FIG. 1 is a cross-sectional view of a pixel of a known spatially coherent two-colour IR detector, showing a single contact bump through which both colours are detected;

FIG. 2 is a cross-sectional view of a simultaneous two-colour photon detector in accordance with the invention, showing two contact bumps, contacting n-type material only; and

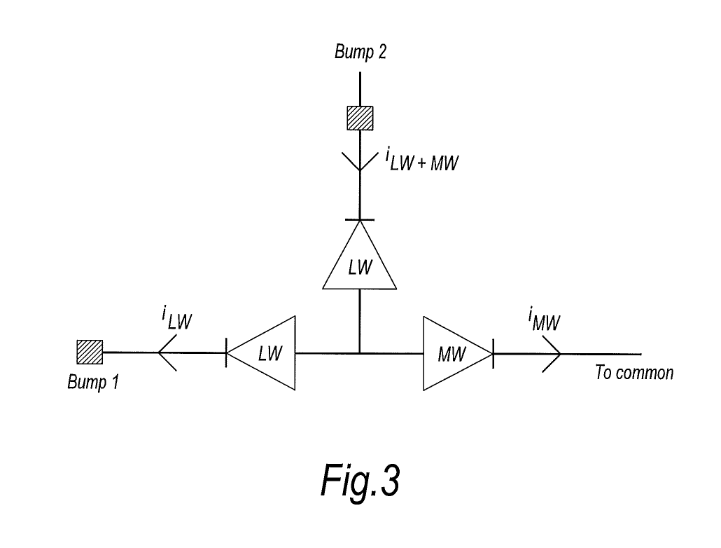

FIG. 3 is a schematic effective circuit diagram of the pixel of FIG. 3. A cross-section of a pixel in accordance with one aspect of the invention is shown in FIG. 2. The effective circuit diagram of the pixel is shown in FIG. 3.

In FIG. 2, a two-colour photon detector includes a substrate 6 on which a mesa-type multi-layered CMT detector structure 10 is monolithically integrated. The detector may be grown by Liquid Phase Epitaxy (LPE), Molecular Beam Epitaxy (MBE), Vapour Phase Epitaxy (VPE) or by any process that is suitable for forming layers of Hg₁₋ₓCdₓTe, where the value of x is selected to set the bandgap energy of the Hg₁₋ₓCdₓTe to provide the desired spectral response for a given layer.

The CMT mesa structure 10 is comprised of a first layer 24 which is an n-type radiation absorbing layer, doped with, for example, iodine at a concentration of approximately 5×10¹⁶ atoms.cm⁻³. Overlying the first layer 24 is a p-type radiation absorbing layer 26 doped with, for example, approximately 3×10¹⁷ atoms.cm⁻³ of arsenic. Overlying absorbing layer 26 is a second layer of n-type radiation absorbing layer 28 doped with, for example, iodine at a concentration of approximately 5×10¹⁶ atoms.cm⁻³. The absorbing layers 26, 28 must be thick enough to absorb most of the incident photons. The required thickness can be roughly approximated as a thickness comparable to the wavelength of the photons being absorbed. It will be appreciated that the materials and dopant concentrations are given as examples only and that any suitable material or dopant concentration may be used.

The substrate 6 is comprised of, for example, gallium arsenide GaAs, epitaxial GaAs on silicon (GaAs:Si), CdZnTe, CdTe, CdTe:Si or CdTe:sapphire or other material that is substantially transparent to radiation having wavelengths of interest. In operation, radiation is incident upon a bottom surface 42 of the substrate 6. An anti-reflection coating may be applied to the bottom surface 42 of the substrate 6 to improve efficiency. It may be appropriate, if an anti-reflection coating is used, to remove the substrate 6 from the detector structure. It will be appreciated that this will depend on the specific application of the detector 2.

A common layer may be used to define the cut-on for wavelength band 1. With an CMT composition such that the layer absorbs all wavelengths below 2 μm for example, the common layer is heavily doped to have a short diffusion length. Holes generated by wavelengths below 2 μm will not reach the junction and so will not give a signal.

A bump 12 of indium may be used to bond each mesa 10 to a silicon processor via a window etched in a passivation layer. Another metal may be deposited between the indium and the CMT to reduce the possibility of unwanted interdiffusion between the indium and the CMT.

A suitable bias potential is applied between the common layer and the bump 12. For the connection to the common layer, the passivation on the diodes on the perimeter of the array is removed and a metal film deposited down the side of these mesas 10 to short the bump 12 to the common layer. The bumps 12 on these perimeter diodes are then used to connect to the common layer 44. The path taken by current between bump 2 and the array common is a standard two-colour structure as shown in FIG. 1. Between the two bumps 12 is the same structure, but with the same absorber on both sides of the barrier layer.

Bump 12a is held at the same bias as the array common. Bump 12b is biased negatively with respect to bump 12a. Therefore the mid-wave (MW) signal will be detected through a circuit which passes between bump 12b and the common. The long-wave (LW) signal will be detected through a circuit which passes between the two bumps 12.

The LW signal comes from the area of the upper absorber that is connected to bump 12a. The area of upper absorber connected to bump 12b cannot contribute to the LW signal. Therefore a trench 30 is disposed between the bumps 12, but preferably should be as close to bump 12b as possible.

It will be appreciated that, using this design, two spatially and temporally coherent colours can be detected without needing to make electrical contact to any intermediate layers within the structure, particularly contacts to p-type materials that are notoriously difficult to contact to in CMT. i.e. only the uppermost 28 and lowermost 24 layers require contacts: the uppermost 28 through the two bumps 12, and the lowermost 24 through the array common 8.

It will further be appreciated that this design has a number of further advantages over existing designs. For example, only one trench 30 is required for each pixel, minimising the amount of pixel area lost to trench etching; the trench 30 is needed solely to divide the upper layer 28 between the two bumps 12, and can therefore be made as narrow as possible; and with an n-p-n structure as shown in FIG. 3, no metal contacts to p-type material are required.

Photocurrents from the detector are read out using a multiplexer or Read Out Integrated Circuit (ROIC). An ROIC is a silicon integrated circuit designed for this purpose. For each diode in the array there is a corresponding input circuit in the ROIC. The indium bumps 12 are used to connect each diode to the corresponding input circuit. Each input circuit has a capacitor that stores photocurrent collected over a defined time period. The stored charges are then read out row by row and subsequently processed as required.

As the top of each mesa is required to carry an indium bump, there is a limit to the thickness of the CMT layers. Typically, the mesa depth is approximately 8.5 μm with an array pitch of approximately 30 μm, although other depths and pitches are possible.

Having now described embodiments of the invention, numerous modifications will become apparent to the skilled person. For example, the cut-on for wavelength band 1 could be set by a suitable optical filter rather than or in addition to the composition of the common layer 44. The first absorbing layer 24 may be p-type CMT in which case the p-n junction is between the first absorbing layer 24 and the common layer 44. It is therefore preferable to etch the slot depth into the common layer 44 to prevent electrical cross-talk between adjacent pixels.

1. An electromagnetic radiation detector responsive to two discrete wavelength ranges comprising a plurality of layers of semiconductor material comprising:
a substrate substantially transparent to electromagnetic radiation within and between the wavelength ranges;
a first layer, doped to provide a first type of electrical conductivity, having a bandgap selected for absorbing radiation within a first wavelength range;
a second layer, doped to provide a second type of electrical conductivity, having a bandgap selected for absorbing radiation within a second wavelength range;
a third layer, doped to provide the first type of electrical conductivity, having a bandgap selected for absorbing radiation within a third wavelength range;
in which the first and third layers are doped n-type and the second layer is doped p-type.

2. A detector as claimed in claim 1 further comprising two contact points disposed on the third layer.

3. A detector as claimed in claim 2, in which the third layer is divided into two sections by a trench, the trench acting so as to isolate the contact points from each other.

4. A detector as claimed in claim 2, in which the contacts contact points are formed from metal deposited onto the pixel, the metal being bonded only to the n-type material.

5. A detector as claimed in claim 1, in which, the semiconductor material is comprised of Group II-VI semiconductor material.

6. A detector as claimed in claim 1, comprising an anti-reflection coating disposed on a surface of the substrate, the substrate surface being a radiation-admitting surface of the detector.

7. A detector as claimed in claim 1, wherein the two wavelength ranges are 2 μm to 2.5 μm and 3.7 μm to 4.5 μm.

8. A detector as claimed in claim 1, wherein the substrate is comprised of gallium arsenide, gallium arsenide on silicon, cadmium telluride, cadmium zinc telluride, cadmium telluride on silicon or cadmium telluride on sapphire.

9. A detector as claimed in claim 1, wherein a lower limit of the first wavelength range is modified by the composition of a layer in the detector.

10. A detector as claimed in claim 1, wherein a lower limit of the first wavelength range is modified by an optical filter.

11. A detector as claimed in claim 1, wherein the electromagnetic radiation detector is a photodiode.

12. (canceled)
